(19) United States
(12) Patent Application Publication
(10) Pub. No.: US 2007/0173075 A1
(43) Pub. Date: Jul. 26, 2007

(54) Laser-based method and system for processing a multi-material device having conductive link structures

(76) Inventors: Joohan Lee, Andover, MA (US); James J. Cordingley, Littleton, MA (US); Bo Gu, North Andover, MA (US); Jonathan S. Ehrmann, Sudbury, MA (US); Joseph J. Griffiths, Winthrop, MA (US)

Correspondence Address: BROOKS KUSHMAN P.C., 1000 TOWN CENTER, TWENTY-SECOND FLOOR, SOUTHFIELD, MI, 48075, US

(21) Appl. No.: 11/699,297

(22) Filed: Jan. 29, 2007

Related U.S. Application Data
(63) Continuation-in-part of application No. 11/441,763, filed on May 26, 2006.
Application No. 11/441,763 is a continuation of application No. 11/125,367, filed on May 9, 2005, now Pat. No. 7,192,846.
Application No. 11/125,367 is a division of application No. 10/108,101, filed on Mar. 27, 2002, now Pat. No. 6,972,268.
(60) Provisional application No. 60/765,291, filed on Feb. 3, 2006.
(60) Provisional application No. 60/279,644, filed on Mar. 29, 2001.

(51) Int. Cl. H01L 21/00

(52) U.S. Cl. 438/795

(57) ABSTRACT

A laser-based method and system for selectively processing a multi-material device having a target link structure formed on a substrate while avoiding undesirable change to an adjacent link structure also formed on the substrate are disclosed. The method includes applying at least one focused laser pulse having a wavelength into a spot. The at least one focused laser pulse has an energy density over the spot sufficient to completely process the target link structure while avoiding undesirable change to the adjacent link structure, the substrate and any layers between the substrate and the link structures. The target link structure and the adjacent structure may have a pitch of about 2.0 microns or less.

### CROSS-REFERENCE TO RELATED APPLICATIONS AND PATENTS

This application claims the benefit of U.S. provisional application Ser. No. 60/765,291, filed Feb. 3, 2006. This application is a continuation-in-part of U.S. Ser. No. 11/441,763, filed May 26, 2006. That application is a continuation application of U.S. Ser. No. 11/125,367, filed May 9, 2005, which, in turn, is a divisional application of the application which resulted in U.S. Pat. No. 6,972,268, which claims the benefit of U.S. provisional application Ser. No. 60/279,644, filed Mar. 29, 2001. This application is related to U.S. Ser. No. 11/130,232, filed May 17, 2005 which, in turn, is a continuation application of the application which resulted in U.S. Pat. No. 6,911,622 which, in turn, is a continuation which resulted in U.S. Pat. No. 6,559,412 which, in turn, is a continuation of the application which resulted in U.S. Pat. No. 6,300,590.

The following U.S. patents are hereby incorporated by reference in their entirety:

U.S. Pat. No. 6,911,622 (the '622 patent) entitled “Laser Processing”;

U.S. Pat. No. 6,949,844 (the '844 patent) entitled “High-Speed Precision Positioning Apparatus”;

U.S. Pat. No. 6,727,458 (the '458 patent) entitled “Energy-Efficient, Laser-Based Method And System For Processing Target Material”;

U.S. Pat. No. 6,972,268 (the '268 patent) entitled “Methods And Systems For Processing A device, Methods And Systems For Modeling Same And The Device”; and

U.S. Pat. No. 6,987,786 (the '786 patent) entitled “Controlling Laser Polarization.”

### BACKGROUND OF THE INVENTION

1. Field of the Invention

This invention generally relates to laser processing systems and methods, including systems and methods for removing, with high yield, closely-spaced conductive link structures or “fuses” on a substrate of an integrated circuit or memory device.

2. Background Art

The following exemplary non-patent references relate to laser memory repair processes and interconnect technology:
[1] J. Lee, J. Ehrmann, D. Smart, J. Griffiths and J. Bernstein “Analyzing the Process Window for Laser Copper-link Processing” Solid State Technology, pp. 63-66, December, 2002.
[2] J. B. Bernstein, J. Lee, G. Yang, and T. Dahmas, “Analysis of Laser Metal-cut Energy Process Window,” IEEE Semiconduc. Manufact., Vol. 13, No. 2, pp. 228-234, 2000.
[3] J. Lee, J. B. Bernstein, “Analysis of Energy Process Window of Laser Metal Pad Cut Link Structure,” IEEE Semiconduc. Manufact., Vol. 16, No. 2, pp. 299-306, May 2003.
[4] J. Lee and J. Griffiths “Analysis of Laser Metal Cut Energy Process Window and Improvement of Cu Link Process by Unique Fast Rise Time Laser Pulse,” Proceedings of Semiconductor Manufacturing Technology Workshop, pp. 171-174, Hsinchu, Taiwan, December 2002.
[5] LIA Handbook of Laser Materials Processing, Chapter 19, pp. 595-615 “Link/Cutting Making,” Ed. in Chief Ready, Laser Institute of America, 2001.

FIG. 14 of [5] shows “Link pitch” (or “fuse pitch”) is the center-to-center spacing between adjacent links. Typical link dimensions reported in the reference include lengths of 7-10 microns, thickness of 0.5 microns, and width of 0.8-1 μm. As noted therein, link pitch is subject to periodic shrinks.

Chapter 19 of [5] also shows various arrangements of links on die, typically groups of links having a pre-determined pitch. The links are generally arranged in rows and column. Sometimes the links are staggered as shown in FIG. 15, page 601 of [5].

Reference [5] indicates designers would like to avoid adjacent link damage. Such damage was attributed to at least spot size, link width, and position error. The present trend is toward 1 micron pitch structures having link widths well below a visible wavelength of light (<0.4 μm, and below 0.1 μm).

Conventional near IR laser based systems, for instance those using 1-1.3 μm wavelengths, have limited process capability—no finer than about 2.0 μm pitch. The diffraction limited spot size and depth of focus (DOF) are two specific limiting factors. Now, as fuse pitches continue to decrease to about 1 micron, neighbor fuse damage is also major failure mode which further limits processing capability at long wavelengths. The benefit of reduced substrate damage is offset by such limiting factors.

Additional margin, so to avoid substrate damage or collateral link damage, may be provided for fine pitch by the shielding layers or other material modification, for instance as disclosed in EP published application No. 0902474, and U.S. Pat. Nos. 5,936,296; 6,057,180; 6,297,541; 6,320,243; 6,664,173; and 6,979,798. The links may have one or more passivation layers between the incident beam and the link. Similarly, there may be one or more metal or dielectric layers between the link and substrate. Link materials may be aluminum, copper, gold, polysilicon or other suitable materials.

Numerous memory devices include multi-level, stacked link structures having highly conductive aluminum lines, with overlying and/or underlying metal films.

The metal film materials may selected based on various physical properties, including optical properties. For example, TiN offers protection from oxidation and minimizes contact of the metal interconnect with SiO₂. However, TiN is also useable as an anti-reflection coating (ARC) at certain wavelengths. For example, high absorption is advantageous in lithography steps for patterning of interconnects (metal lines). A standard UV wavelength of 266 nm is often used for the patterning.

U.S. Pat. Nos. 5,936,296 (the '296 patent) and 6,320,243 (the '243 patent) further disclose TiN, TiW, and Ti/TiN ARCs, various associated properties, and various link (fuse) structures. The benefits of ARC are recognized to provide for a reduction in laser energy. This in turn reduces stress on peripheral elements and can reduce adjacent (neighbor) link damage. Specific reference is made to at least cols. 3 and 9 of the '296 patent, and cols. 3, 6, and 7 of the '243 patent for further information.

### SUMMARY OF THE INVENTION

An object of the present invention is to provide laser-based methods and systems for processing multi-material devices having conductive link structures.

In carrying out the above object and other objects of the present invention, a method of laser processing a multi-material device including a silicon substrate, conductive target and adjacent link structures and at least one inner dielectric layer which separates the link structures from the silicon substrate is provided. The method includes generating at least one focused laser pulse which has a predetermined visible or near UV wavelength long enough to sufficiently tolerate variations of at least one of the thickness and reflectance of a layer of the device or variations over a batch of the devices. The silicon substrate has a relatively high absorption coefficient at the predetermined wavelength. The at least one dielectric layer has a relatively low absorption coefficient at the predetermined wavelength. The method further includes applying the at least one focused laser pulse which has the predetermined wavelength into an approximate diffraction-limited spot during motion of the substrate relative to the at least one focused pulse. The spot has a 1/e² spot diameter in a range of about 0.5-1.5 microns. The at least one focused laser pulse has an energy density over the spot sufficient to completely process the target link structure while avoiding undesirable change to the adjacent link structure, the substrate and any layers between the substrate and the link structures. The target link structure and the adjacent link structure have a pitch of about 2.0 microns or less.

The step of generating may generate a pulsed laser output having a wavelength below an absorption edge of the substrate and in the range of about 0.3-0.55 microns.

The step of applying may include the step of directing the pulsed laser output at the target link structure at an incident beam energy sufficient to completely process the target link structure.

The target link structure and the at least one laser pulse both have a position. The method may further include generating computer-controlled timing signals synchronized with the position of the at least one pulse relative to the position of the target link structure.

The step of generating computer-controlled timing signals may be based on the position of the at least one laser pulse relative to the position of the target link structure.

The method may further include providing an optical switch and switching the optical switch based on the timing signals to cause a plurality of focused laser pulses to be transmitted to the target link structure.

The step of generating may be performed with a pulsed laser subsystem having a near UV, blue or green wavelength.

The subsystem may include a frequency doubled or tripled MOPA.

The target link structure may have a relatively high absorption at the predetermined wavelength.

The pitch may be about 1.5 microns or less.

The diameter may be about 0.7 microns.

Energy delivered to the target link structure when the pitch is about 1-1.3 microns may be about 0.014 micro joules to less than about 0.055 micro joules over the 0.7 micron diameter.

Energy density over the diameter may be in a range of about 1 J/cm² to about 20 J/cm².

Further in carrying out the above object and other objects of the present invention, a system for laser processing a multi-material device including a silicon substrate, conductive target and adjacent link structures, and at least one inner dielectric layer which separates the link structures from the silicon substrate is provided. The system includes means including a pulsed laser subsystem for generating at least one focused laser pulse having a predetermined visible or near UV wavelength long enough to sufficiently tolerate variations of at least one of the thickness and reflectance of a layer of the device or variations over a batch of the devices. The silicon substrate has a relatively high absorption coefficient at the predetermined wavelength and the at least one dielectric layer has a relatively low absorption coefficient at the predetermined wavelength. The system further includes means for applying the at least one focused laser pulse which has the predetermined wavelength into an approximate diffraction-limited spot during motion of the substrate relative to the at least one focused pulse. The spot has a 1/e² spot diameter in a range of about 0.5-1.5 microns. The at least one focused laser pulse has an energy density over the spot sufficient to completely process the target link structure while avoiding undesirable change to the adjacent link structure, the substrate and any layers between the substrate and the link structures. The target link structure and the adjacent link structure have a pitch of about 2.0 microns or less.

The means for generating may generate a pulsed laser output having a wavelength below an absorption edge of the substrate and in the range of about 0.3-0.55 microns.

The means for applying may include means for directing the pulsed laser output at the target link structure at an incident beam energy sufficient to completely process the target link structure.

The target link structure and the at least one laser pulse both have a position. The system may further include a computer programmed to generate timing signals synchronized with the position of the at least one pulse relative to the position of the target link structure.

The computer may be further programmed to generate the timing signals based on the position of the at least one laser pulse relative to the position of the target link structure.

The system may further include an optical switch and means for switching the optical switch based on the timing signals to cause a plurality of focused laser pulses to be transmitted to the target link structure.

The pulsed laser subsystem may have a near UV, blue or green wavelength.

The subsystem may include a frequency doubled or tripled MOPA.

The target link structure may have a relatively high absorption at the predetermined wavelength.

The pitch may be about 1.5 microns or less.

The diameter may be about 0.7 microns.

Energy delivered to the target link structure when the pitch is about 1-1.3 microns may be about 0.014 micro joules to less than about 0.055 micro joules over the 0.7 micron diameter.

Energy density over the diameter may be in a range of about 1 J/cm² to about 20 J/cm².

The multi-material device may include a multi-layer stack, the stack having at least one dielectric layer over one or more of the link structures.

The diffraction-limited spot may be centered about the target link structure to within about 0.15 μm, wherein damage to the adjacent link structure is avoided.

The laser pulses may be produced at a pulse repetition rate of about 70 KHz or greater.

The multi-material device may also include conductive link structures having a pitch of about 2.0 microns or greater, and wherein timing signals may adjust the speed of movement of the substrate based on the pitch of about 2.0 microns or greater so as to provide for an improvement in throughput.

The pulsed laser subsystem may include a diode-pumped, frequency-doubled laser. The laser may have an infrared (IR) fundamental wavelength and a minimum available pulse repetition rate of at least 50 KHz with available output energy of about 4 μJ or greater at the minimum available pulse repetition rate, residual IR of less than 1% of total power, peak-peak stability of about 5% or better, and output beam quality corresponding to M² of about 1.1 or better.

The above object and other objects, features, and advantages of the present invention are readily apparent from the following detailed description of the best mode for carrying out the invention when taken in connection with the accompanying drawings.

### BRIEF DESCRIPTION OF THE DRAWINGS

FIG. 1 is a schematic view which illustrates typical dimensions of a link target structure; an exemplary laser spot used for processing the link in accordance with an embodiment of the present invention is shown; the dimensions are representative of very-fine pitch link groups;

FIG. 2 is a block diagram schematic view showing some elements of a laser-based memory repair system according to one embodiment of the invention.;

FIGS. 3a and 3b are side cross-sectional views which illustrate examples of link structures and surrounding materials representative of various memory devices;

FIGS. 4a-4e are side cross-sectional views which illustrate exemplary link structures of FIGS. 3a and 3b in more detail (in the upper portion of the Figures), and include corresponding graphs with curves showing wavelength sensitive reflectance properties;

FIG. 5 is a graph with curves which show the absorption of several link materials disclosed in FIG. 3 of the '622 patent and an additional link stack having low reflectance and high absorption at short wavelengths;

FIGS. 6a-6c are graphs which illustrate a relationship between dielectric layer reflectance and dielectric layer thickness at various wavelengths;

FIG. 7 is a graph with curves which illustrate a laser energy process window of various pitch fuse structures (0.8, 1.0, 1.2, 1.5, 1.8, 2.0 and 2.2 μm) from IR laser experiment;

FIGS. 8a and 8b illustrate top-view images of links processed with a laser spot size of 0.7 μm (1/e² diameter); laser energies: (a) from 0.005 μJ to 0.045 μJ and (b) from 0.050 μJ to 0.090 μJ with a 0.005 μJ step, respectively;

FIGS. 9a and 9b are SEMs which illustrate FIB images of laser-cut sites processed with 0.04 μJ at 0.7 μm 1/e² spot in diameter; (a) top view of the processed fuses and (b) cross-sectional view;

FIGS. 10a and 10b are graphs with curves which illustrate electrical measurement results of 300 links processed with 0.7 μm (1/e² spot diameter); link pitch: 1.0 μm, (a) parallel structure for checking cut qualities and (b) serial structure for checking damages to adjacent link structures; and

FIGS. 11a and 11b are graphs with curves which illustrate electrical measurement results (each set has 300 links) processed with 0.04 μJ and 0.7 μm 1/e² spot in diameter; link pitch: 1.0, 1.1, 1.2 and 1.3 μm, (a) parallel structure for checking cut qualities and (b) serial structure for checking damages to adjacent link structures.

### DETAILED DESCRIPTION OF THE PREFERRED EMBODIMENTS

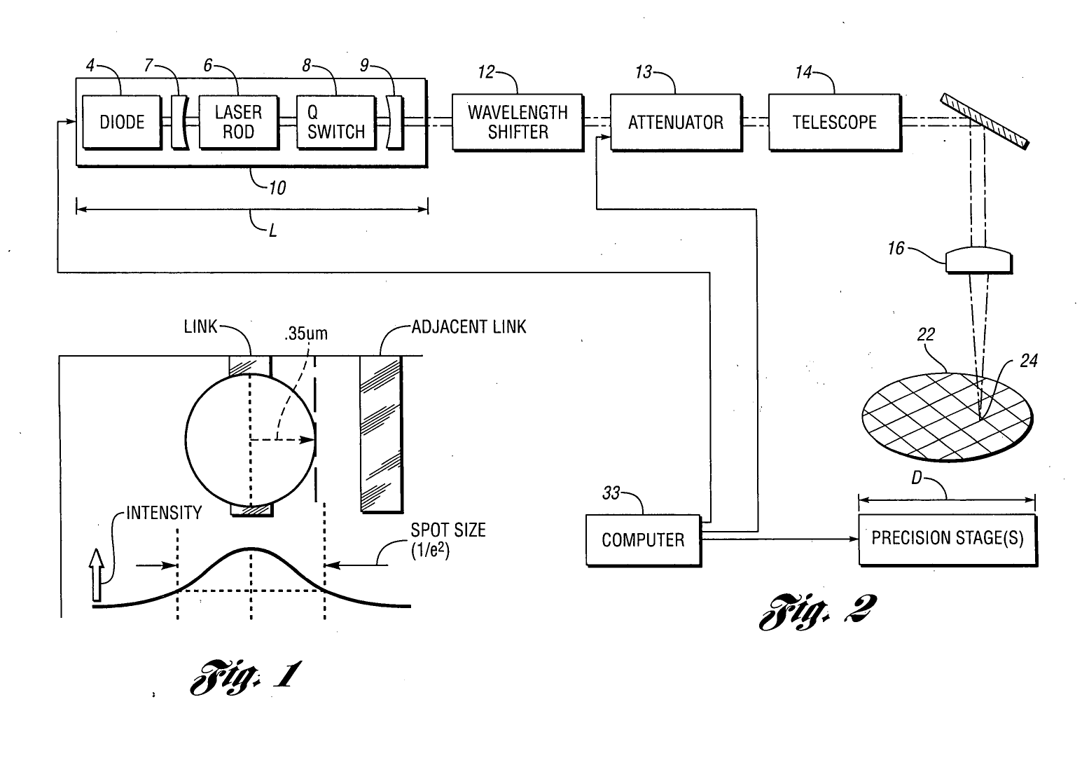

FIG. 1 (not to scale) illustrates typical dimensions of a target link structure, and an exemplary laser spot used for processing the link structure in accordance with an embodiment of the present invention. The dimensions are representative of very-fine pitch link groups. The target link structure may be separated from the substrate by one or more dielectric layers. The substrate is typically Silicon, but may include other semi-conductive, insulating, or other suitable materials.

A method and system for processing very fine pitch link structures of a multi-material semiconductor memory device is disclosed. In at least one embodiment the method includes applying at least one laser pulse to a target link structure. The at least one laser pulse has a short wavelength below the absorption edge of the silicon substrate. The at least one laser pulse provides sufficient energy density over a spot size small enough to cleanly remove the link and avoid unacceptable damage to neighbor links. The energy density of the at least one laser pulse is also small enough to avoid unacceptable damage to the substrate, and to any functional layers between the link structure and the substrate.

A system for processing very fine pitch link structures of a multi-material semiconductor memory device is disclosed. In at least one embodiment the system includes a laser pumping source, a laser resonator cavity configured to be pumped by the laser pumping source, and a laser output system configured to produce a laser output from energy stored in the laser resonator cavity and to direct the laser output at the target structure on the silicon substrate in order to vaporize the target structure, at a wavelength below an absorption edge of the silicon substrate and in the range of about 0.3 to 0.55 microns. The silicon substrate is positioned beneath the target structure with respect to the laser output. The laser output system is configured to produce the laser output at an incident beam energy. The system also includes a computer programmed to generate computer-controlled timing signals synchronized with the position of the pulsed laser beam relative to the target structure, and an optical switch that is controllably switchable based on the timing signals so as to cause output pulses of the pulsed laser beam to be transmitted to the target structure. The incident beam energy at which the target structure is vaporized is reducible relative to an incident beam energy necessary to deposit unit energy in the target structure sufficient to vaporize the target structure at a higher wavelength below the absorption edge of the silicon substrate.

A method of processing very fine pitch link structures of a multi-material semiconductor memory device is disclosed. The method includes the steps of providing a laser system configured to produce a laser output at a wavelength below an absorption edge of the silicon substrate and in the range of about 0.3-0.55 microns, and directing the laser output at the target structure on the silicon substrate at the wavelength and at an incident beam energy, in order to vaporize the target structure. The silicon substrate is positioned beneath the target structure with respect to the laser output. The method also includes the steps of generating computer-controlled timing signals synchronized with the position of the pulsed laser beam relative to the target structure, and controllably switching an optical switch based on the timing signals so as to cause output pulses of the pulsed laser beam to be transmitted to the target structure. The incident beam energy at which the target structure is vaporized is reducible relative to an incident beam energy necessary to deposit unit energy in the target structure sufficient to vaporize the target structure at a higher wavelength below the absorption edge of the silicon substrate.

By way of example, specific reference is made to at least Col 3, Line 1-Col 4 Line 4 and corresponding figures of the '622 patent. A link blowing system is disclosed for short wavelength processing wherein coupling of energy into the target structure and substrate absorption are both considered at wavelengths where the substrate is not very transparent.

A method of processing very fine pitch link structures of a multi-material semiconductor memory device is disclosed In at least one embodiment the method may include laser processing a multi-level, multi-material device including a substrate, a conductive link and a multi-layer stack, the stack having at least two inner dielectric layers which separate the conductive link from the substrate is disclosed. The method includes: generating a pulsed laser beam having a predetermined wavelength less than an absorption edge of the substrate, the substrate having a relatively high absorption coefficient at the predetermined wavelength and the stack having a low absorption coefficient at the predetermined wavelength and including at least one laser pulse wherein at least reflections of the laser beam by the layers of the stack substantially reduce pulse energy density at the substrate relative to at least one other wavelength; and processing the conductive link with the at least one laser pulse wherein pulse energy density at the conductive link is sufficient to remove the conductive link while avoiding damage to the substrate and the inner layers of the stack.

By way of example, specific reference is made to at least the following sections of the '268 patent: FIGS. 1a-1c, 3, 4a-4c, 5a-5b, 6a-6b, 7a-7b, 8, 9, and the corresponding text. The cited sections of the '268 patent teach aspects of laser-material interaction with multi-material devices. The teachings include processing of fine pitch devices, wherein a stack with multiple dielectric layers separates the link and substrate. Processing is generally to be carried out at wavelengths below the absorption edge of silicon, and at wavelengths above the absorption edge of a multi-layer dielectric stack.

In at least one embodiment processing may be carried out a short visible wavelength. The visible wavelength may produce a larger process energy window relative to that achievable at a shorter UV wavelength.

FIG. 2 is a schematic that illustrates some elements of a laser-based memory repair system corresponding to an embodiment of the present invention. FIG. 2 is similar to FIG. 1 of the '622 patent except the scanning mirrors 18 and 20 of FIG. 1 are replaced with a precision wafer stage.

Also, a preferred motion control system, including precision stage(s) for wafer motion, is disclosed in the '844 patent. Reference is generally made to FIGS. 1-13 of the '844 patent and the corresponding text. The '844 disclosure generally describes a coarse and fine stage architecture for precision positioning, corresponding analog and digital controllers, and further includes discussion related to trajectory generation and planning for link processing.

Further, the positioning accuracy of the at least one pulse relative to the link is sufficient to avoid the neighbor link damage, and will typically be about 0.15 μm or better (1 mean 1+3*sigma), at a typical 70 KHz link processing rate.

The commercially available model M-455 memory repair machine, available from the assignee of the present invention, includes an NdYVO₄ short pulse laser system as generally shown in FIG. 2, and a preferred motion system as generally described in the '844 patent.

In at least one embodiment of the present invention:

The laser output may be generated by a frequency doubled, diode-pumped, NdYVO4, solid state laser.

The frequency doubled output may produce a 532 nm wavelength.

The laser output may include at least one pulse having pulse width less than about 25 ns, for instance about 15-20 ns.

The laser output incident on the target structure may be focused into a spot having a 1/e² spot diameter in the range of about 0.5-1.5 microns, for instance, about 0.7 μm.

The energy delivered to each target structure of a group of links having about 1-1.3 μm pitch may be about 0.015 μJ to less than 0.055 μJ over a spot size of about 0.7 μm, as measured at the 1/e² diameter, with slightly larger energy for link pitch approaching 1.5 μm.

The energy density, over a 1/e² diameter, may be in an approximate range of about 1 J/cm² to less than 20 J/cm², for processing of various fuse structures. Slightly larger energy may be used for link pitch approaching 1.5 μm.

Preferably the energy density will be less than about 5 J/cm² over the 1/e² spot diameter, and may be less than about 1 J/cm² over the 1/e² diameter.

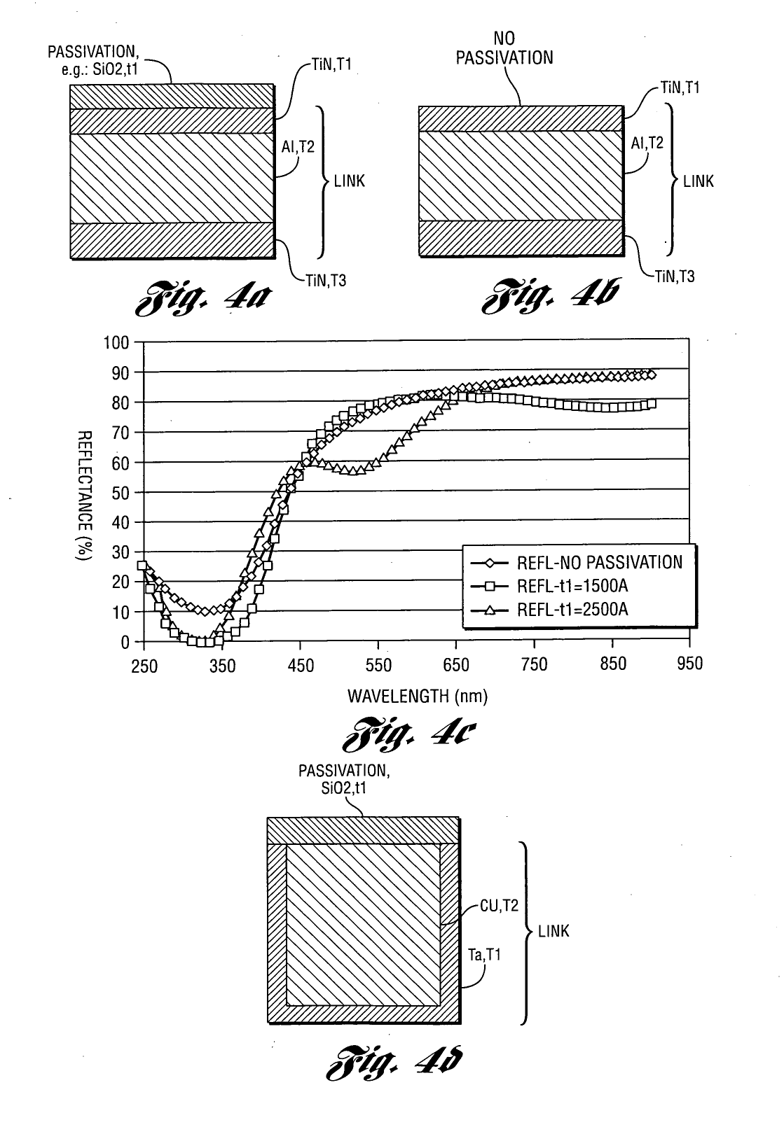

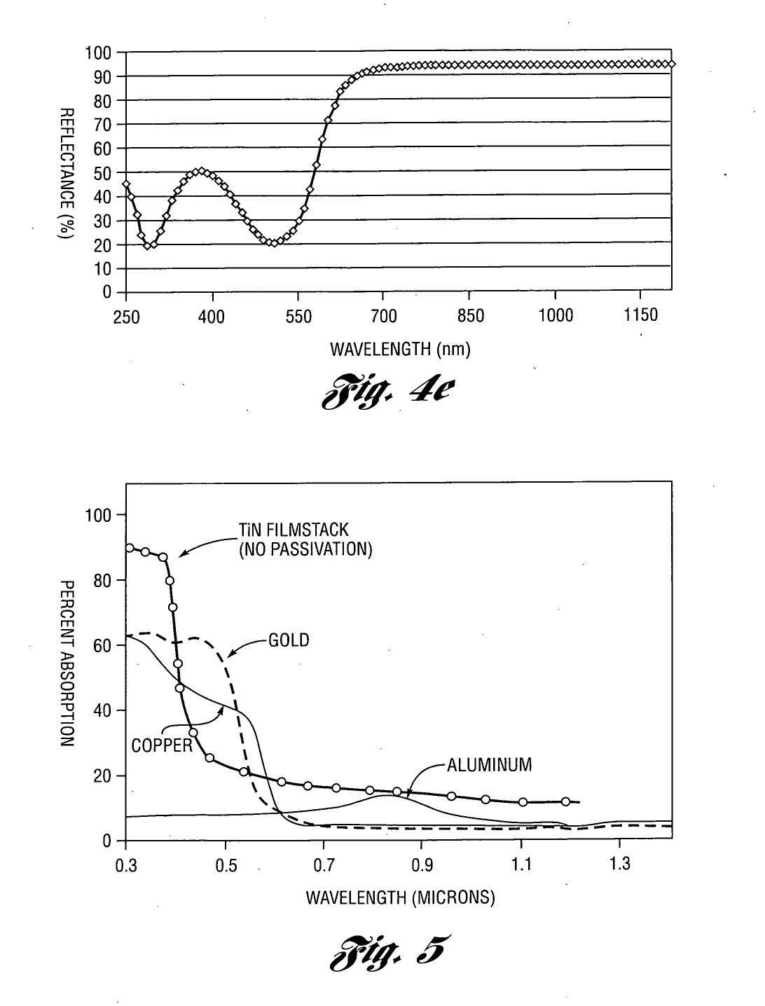

Certain very fine pitch link structures, for instance the stacked structures shown in FIG. 4a, may be processed with about 0.025-0.035 μJ.

A target structure may be a link having a width of about 0.1 μm or less, and spaced about 1-1.5 apart from one or more adjacent links, thereby corresponding to pitch of about less than 1.5 microns, for example 1 μm.

The links may be positioned relative to the at least one pulse with accuracy of 0.15 microns or better (3*sigma).

In at least one exemplary embodiment: the spot size is about 0.7 μm diameter (measured at the 1/e² diameter); a single q-switched pulse having a pulse width about 15-20 ns is applied to the link, and the laser wavelength is 532 nm. The links are arranged with 1.5 micron pitch, and at least one dielectric layer separates the link and substrate.

The second harmonic of the 1.064 μm source, which yields a wavelength in the green portion (532 nm) of visible spectrum, with a near diffraction limited lens, can provide for a minimum 0.7 μm 1/e² spot in diameter at focus. The arrangement provides the same approximate depth of focus (DOF) compared with IR at a spot size of 1.4 μm 1/e² spot in diameter.

In one or more embodiments the laser may be a diode-pumped NdYVO4 laser with the following specifications:

| | |
|---|---|
| Wavelength | 532 nm |
| Energy Output | 4 micro joules available, @ 50-70 KHz |
| Pulse Width | 15 ns @ 50 KHz, 18 ns @ 70 KHz |
| Polarization | 100:1, Linear Vertical |
| Residual IR | <=1% of total power |
| M-squared | 1.1 or better |
| Stability | P-P < 5%., RMS < 2% |

Crystalaser is a supplier of diode-pumped, q-switched lasers.

In one alternative embodiment an output may be produced using a MOPA configuration as shown in the '458 patent with a frequency doubler in the optical path. The output may include a plurality of pulses having a square temporal pulse shape, or other suitable pulse shape.

In at least one embodiment the laser wavelength may be a non-standard laser wavelength in the range of about 400 nm -550 nm. Operation at wavelengths from about 400 nm to about 500 nm may be achieved by frequency tripling a laser having a wavelength in the range of 1.2 to about 1.55 μm.

In at least one embodiment the frequency tripled laser may include a MOPA. The MOPA may include a semi-conductor seed laser, fiber optic amplifier, and frequency tripler.

In another embodiment the laser wavelength may be a frequency tripled output of a near IR laser, in the range of about 0.3 μm to 0.4 microns, and above the absorption edge of an inorganic dielectric layer.

Further, in the wavelength range of blue through violet, there are many choices:

A. Solid State Lasers

| | Nd: YAG/Nd: YV04 | Nd: YLF |
|---|---|---|
| UV | 266 nm | 262, 263 nm |
| Violet | 355 nm | 349, 351 nm |
| Blue | 473 nm | 447, 438 nm |

(1) Similar wavelengths can be obtained from fiber or disk lasers through harmonics;

(2) Ti:sapphire laser tunable from 380-465 nm SHG of Ti:sapphire laser;

(3) Rare earth doped solid state or fiber lasers plus harmonics that will generate wavelengths in the 350-490 range. Many examples can be found in the literature.

B. Semiconductor Lasers

(1) The quest for a blue laser started with II-VI zinc-selenide compounds, but striking achievements have been made with wide-gap III-V nitride materials, which emit light with a much shorter wavelength. While the wavelength of blue laser is around 450 nm, that of GaN lasers is around 400 nm (from 380 to 450 nm);

(2) Use SHG lightwave guide element (like LiNbO3), a 425-nm laser can be obtained from an 850-nm diode laser.

C. Gas-ion Lasers

Wavelengths achievable with gas-ion lasers include 375, 420, 450, 514.5 nm.

Materials and Optical Properties:

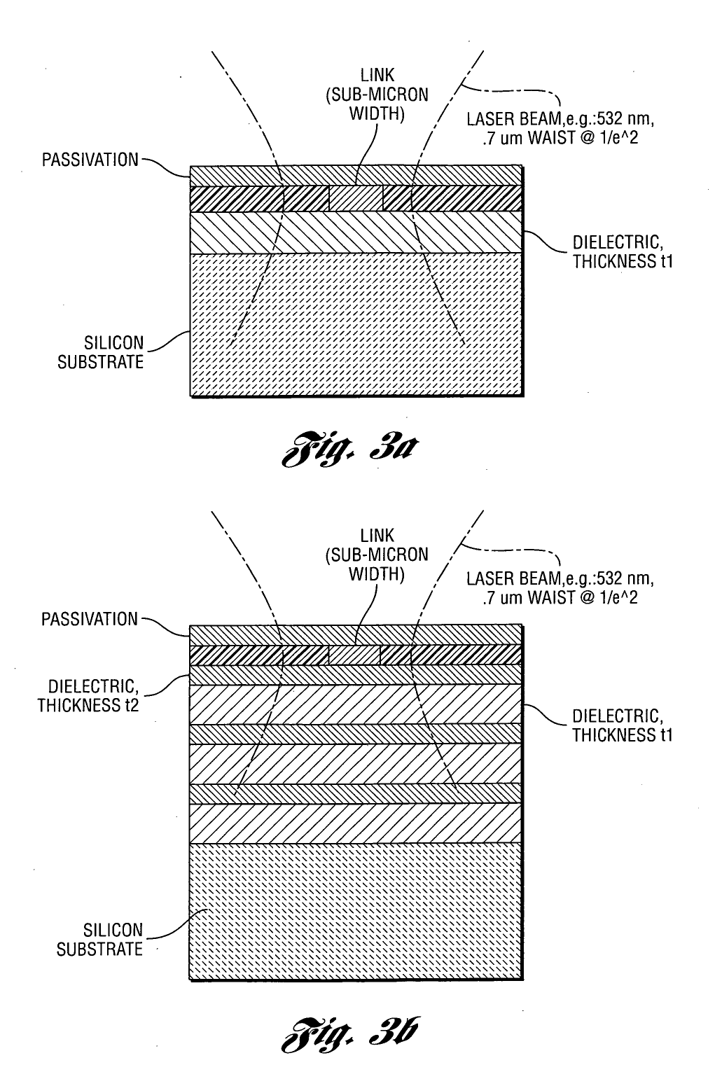

FIGS. 3a and 3b each illustrate a portion of a wafer having a link and surrounding materials.

FIG. 3a shows a conventional arrangement having a link and overlying passivation layer separated from the substrate by a single dielectric layer.

FIG. 3b shows another device structure with a link as in FIG. 3a, but surrounded by a multi-level stack. An exemplary stack may have numerous pairs of dielectrics of differing thickness t1 and t2. The inner layers form a multi-layer dielectric stack that separate the substrate and link The stack elements may be one or more inorganic dielectric materials, for instance SiO₂ or other material having similar optical and thermal properties. The materials may also include organic or low-k dielectric materials, and such materials may have varying optical properties with laser wavelength.

FIG. 3 and corresponding text of the '268 patent illustrates general wavelength sensitivity of a specific stack of inorganic dielectric materials. The spectral reflectance was modeling in a near infrared region. As shown, such a stack may decrease the energy incident on the substrate at selected wavelengths as a result of an interference effect.

Some link materials include a stack of conductive materials. The stack materials may be selected from various combinations of Aluminum, Copper, Gold, Tungsten, Titanium, Polysilicon, various refractory metals, metal nitrides, or other suitable materials.

As shown in FIGS. 4a-4e, a link structure may include a TiN/Al/TiN or others disclosed in the '296 and '243 patents. The TiN (or alternatively TiN/Ti) reflectance generally decreases at short wavelengths(ARC). The reflectance is shown as a function of wavelength for a few thickness choices, and for a case where no passivation layer covers the link.

Sometimes one or more overlying passivation layers may be removed (etched) for link processing. As can be seen from FIGS. 4a, the reflectance is roughly 70% at green wavelength and substantially less than at longer conventional wavelengths (e.g.: 1.047, 1.064, 1.32 μm). The removal of the overlying passivation layer increases the reflectance significantly at near UV wavelengths. As such, increased laser energy is required for processing. The increased energy increases the risk of substrate and adjacent link damage.

FIG. 4d shows an example of another link structure, in this case a Copper fuse. The graph shows absorption is maximized near a standard green wavelength of 532 nm. This type of link structure is typical of the Dual Damascene process as reference in the '268 patent and some non-patent references therein.

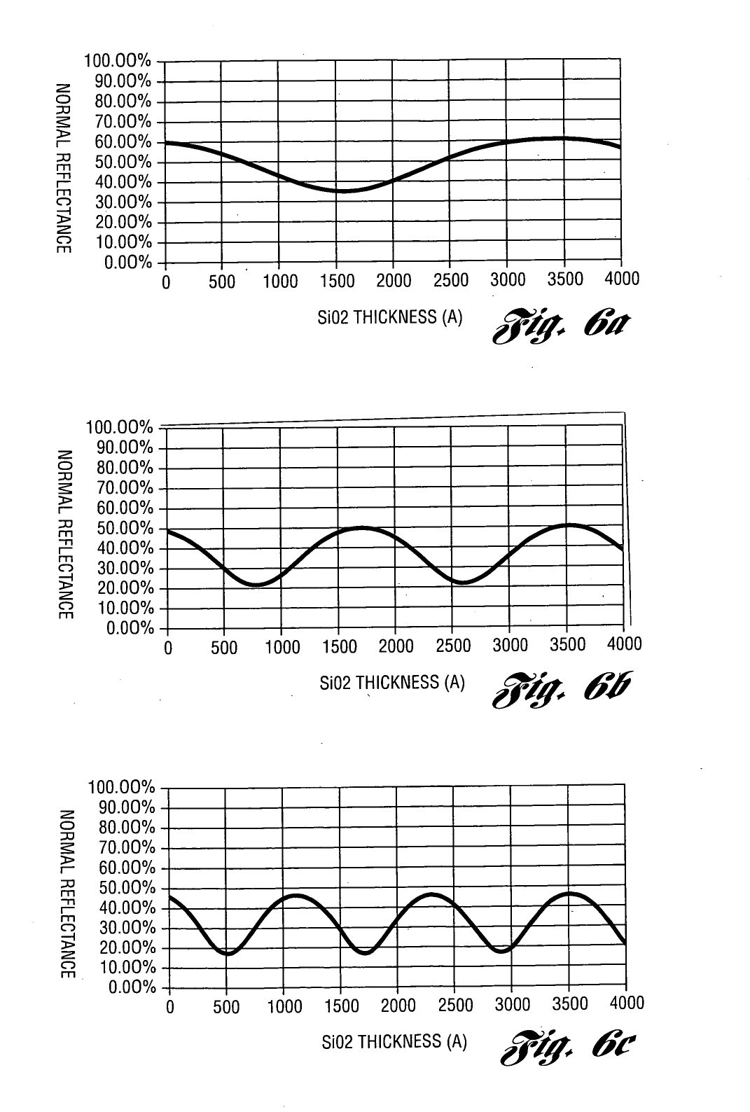

FIG. 5 shows the absorption of several metal link materials as disclosed in FIG. 3 of the '622 patent, and additional link materials having high optical absorption at short wavelengths down to about 300 nm. A typical link structure having TiN or other similar ARC overcoat/undercoat curve is included for rough comparison (e.g.: similar to that of FIG. 4a). A link blowing system is disclosed for short wavelength processing wherein coupling of energy into the target structure and substrate absorption at wavelengths are both considered at wavelengths where the substrate is not very transparent. The TiN provides for increase coupling at short wavelengths in the range of about 300-550 nm.

Optical properties of the Silicon substrate are also of general interest, and illustrated by two publications are cited herein:

Donald Rapp, “Thermo-Optical Properties of Silicon”

Haapalinna et. al., “Spectral Response of Silicon Photodiodes,”

Applied Optics, Vol 37, No. 4, 1 Feb. 1998

The publications are incorporated by reference in their entirety. Plots of spectral reflectance and absorption are shown, including results based on Si covered with SiO₂. Spectral reflectance and absorption curves of Si have also been published in numerous other publications and handbooks.

Increased reflectance of Si at wavelengths below about 400 nm can also affect performance, and useful to consider for modeling and/or predicting link blowing performance at short wavelengths results. The Si absorption and reflectance increases as shown FIG. 1, 3, and 4 of the Rapp publication (increases for Si detector and Si substrates generally). The Haapalina et al. publication also shows some polarization sensitivity in FIGS. 2 and 3 in the UV range, wherein the photodiode was described as SiO₂ (e.g: corresponding to an inner layer) on Si.

The polarization sensitivity is interesting, particularly when the high N.A. of the beam delivery optics is considered. The '786 patent generally teaches adjustment of polarization to increase the energy processing window, including the upper end of the energy window to avoid neighbor link damage.

The increased reflectance at the UV wavelengths may also result in increased adjacent link damage of very fine pitch devices.

Manufacturing tolerances of various materials can limit yield at short wavelengths. The laser energy required for link processing may need frequent adjustment. At longer wavelengths the energy required for link processing is less sensitive to oxide thickness or other thickness variations and reflectance variations of the substrate.

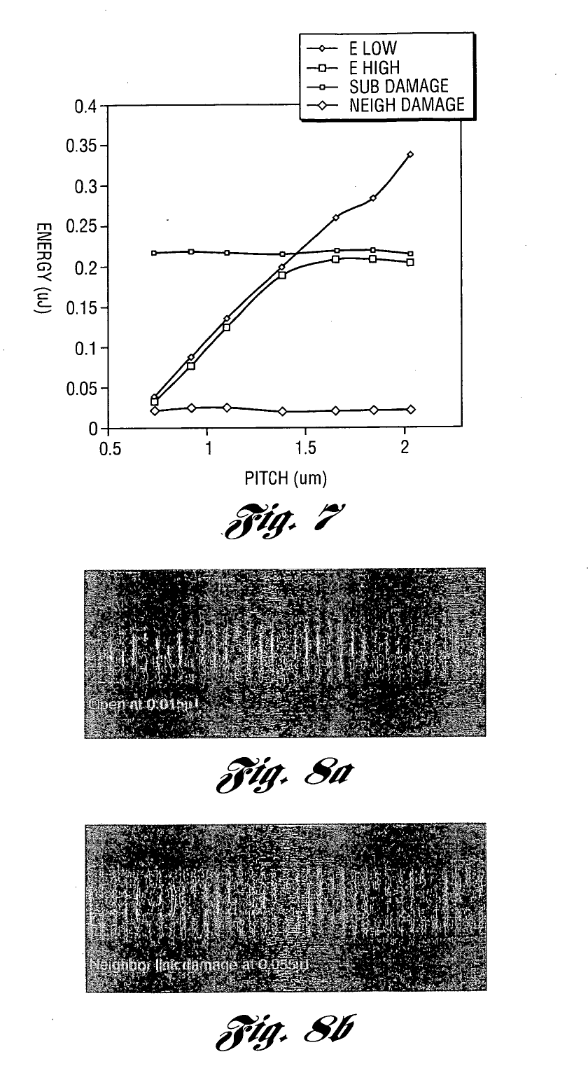

Some test results indicated dielectric thickness variations can affect link processing performance at short wavelengths. FIGS. 6a-6c illustrate a relationship between reflectance and dielectric layer thickness at various laser wavelengths for a stack having an overlying oxide layer. Generally 0.05 (500 Angstroms) micron variation in thickness of the SiO₂ can produce about 2:1 change in reflectance at short wavelengths. The simulation results show more rapid variation with decreasing wavelengths, as evident with comparison of 532 nm and 355 nm results. Performance data suggests that manufacturers may need to provide for increasing control of the dielectric thickness so to obtain best performance at short wavelengths, particularly at short UV wavelengths.

At least some data suggests operation at short visible wavelengths (e.g.: wavelengths greater than 400 nm) will provide for more consistent performance. For instance, visible wavelengths in the range of 400 nm-550 nm the reflectance and sensitivity to thickness is decreased while providing for decreased spot sizes for processing very fine pitch devices.

The '268 patent teaches at least one method and system for decreasing system sensitivity to such variations. Measurement of thickness and adjustment of laser power are disclosed in FIGS. 11-13 and the corresponding text of the '268 patent.

### Very-fine Pitch Laser Processing Example and Results

### Energy Process Window

The energy process window is a figure of merit used to characterize link processing results, a larger window provides increased process tolerance.

FIG. 7 displays experimental results showing how to understand the laser energy process window of a laser metal cut process with a variation of fuse pitch. There were 7 different fuse pitches (0.8, 1.0, 1.2, 1.5, 1.8, 2.0 and 2.2 μm) and each pitch has 5 different fuse widths (0.2, 0.24, 0.3, 0.4, 0.5 and 0.6 μm). This results in a total of 35 fuse structures.

Each data point in FIG. 7 indicates an average value of data from 5 different structures with different widths at each specified pitch. A 1065 nm wavelength IR laser beam with 1.5 μm 1/e² spot size and 21 ns pulse width was used to perform this experiment. The E_{low} curve (E_{low}) shows the minimum energy levels at which each structure required to cut successfully without material remaining at the bottom of cut site. The SUB DAMAGE and NEIGH DAMAGE curves indicate the energy levels that damages to the Si substrate and adjacent fuses occurred, respectively. These two curves show that energy levels for damage to adjacent fuse structures decrease with shrinking fuse pitch, whereas energy levels for substrate damage stay about the same.

The E_{high} curve (E_{high}) indicates the maximum energy level that can be used to process each structure without any damage, and the results were determined based on the two failure modes. When the pitches are larger than 1.5 μm or so, E_{high} was limited by Si substrate damage (SUB DAMAGE curve) and neighbor fuse damage (NEIGH DAMAGE curve) occurred at higher levels. However, neighbor fuse damage occurred at lower energy levels than Si substrate damages with a decrease of pitch to less than 1.5 μm. In other words, neighbor fuse damages occurred at lower energy levels than substrate damages and limits the whole process window for tight pitch structures. Therefore, a smaller spot size is required in order to process tight pitch structures of 1.5 μm or less.

It is noted that this data was based on controlled, accurate alignments and the actual cross-over pitch of neighbor fuse to substrate damages at 1.5 μm will be likely even larger assuming a real production process. Lower corner cracking of aluminum link was not evaluated because the data was decided based on the results observed from the top view. However, the link structures were very thin relative to the link width and aspect ratio was less than one (1). Therefore, cracking at lower corners is unlikely and the data is considered to be valid. For further discussion of lower corner cracking see [2], Bernstein et al.

Short wavelength lasers, and reduced spot sizes, can reduce adjacent link damage. For an equivalent F # (number) and aperture objective lens, a shorter wavelength laser allows the laser beam to be focused to a much smaller spot. Furthermore, short wavelength lasers can create larger DOF than IR at the equivalent spot size. As is well known, a small spot and large DOF are both beneficial to the process of fine pitch metal link structures.

The following results show successful processing of metal fuse structures down to 1.0 μm pitch using a minimum 0.7 μm 1/e² spot, 532 nm wavelength laser and employing FIB (Focused Ion Beam) image observations and electrical measurements.

### Experimental Setup

The test wafer, with the aluminum lines, was fabricated using a standard two-level metal CMOS process for this particular short wavelength laser experiment. The metallization, used for this study, was sputtered Al (1% Si, 0.5% Cu) etched to form variously wide fuses and 0.6 μm thick lines. The Al lines were originally undercoated and overcoated with 0.05 μm thick TiN layer. However, an anti-reflection coating (ARC) over-coating TiN layer was etched away in order to optimize the fuse thickness to form 0.35 μm thick metal lines. During this etching process, surrounding SiO₂ was recessed due to etch selectivity compared to aluminum. A passivation layer of 0.7 μm of Si₃N₄, covered the metallization for the purpose of reliability after the laser process.

Testing was carried out with on groups having 1.0 μm˜1.3 μm with a 0.1 μm step. Also, each pitch has 6 different fuse widths (0.1 μm˜0.6 μm with a 0.1 μm step). Therefore, there are a total of 24 different linear aluminum fuse structures. Each structure is designed to have two different formats; one is to check the cut quality (parallel) and the other is to check for any damages to adjacent structures in order to ensure the acceptability of the cut processing (serial). Electrical measurements were conducted after microscopic observations of the processed fuse structures.

The laser system used to perform these experiments was a GSI Group M455 laser processing system. The system employs a diode-pumped, Q-switched, frequency doubled Nd:YVO₄ laser (532 nm) operated in the saturated single-pulse mode. Pulses, with lengths of approximately 19 ns in FWHM scale, were directed through focusing optics to produce a beam of 1/e² diameter of approximately 0.7 μm spot at focus. The 3-sigma positioning accuracy of the laser system was approximately less than 0.15 μm.

### Experimental Observations

For this experiment, three optimum energies for each structure (a nominal energy of the process window and slightly higher energies) were selected based on laser energy studies and irradiated on each structure.

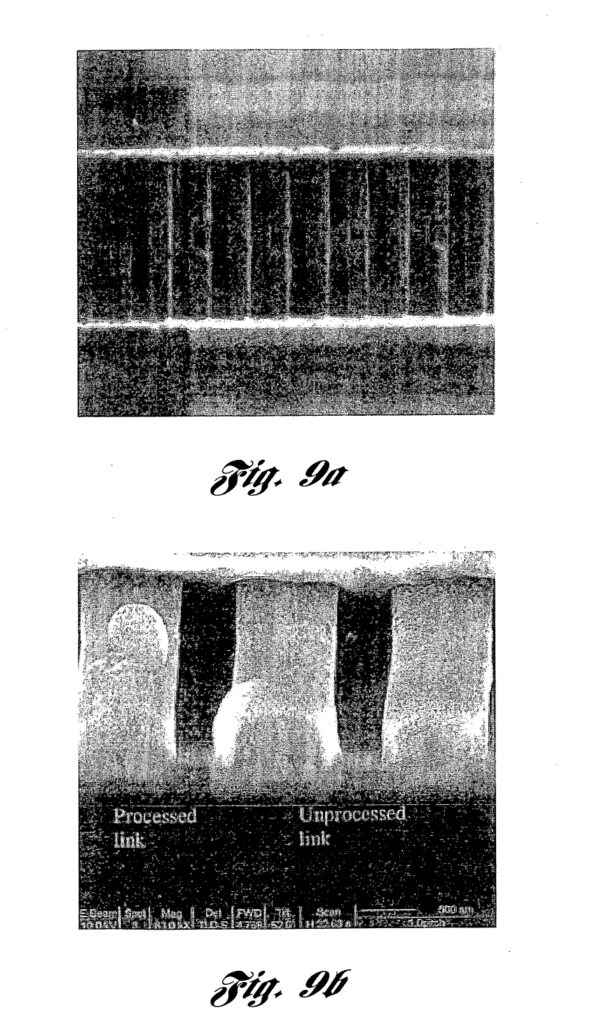

An example of a laser energy process study is shown in FIGS. 8a-8b. It shows a series of links that were a 0.2 μm wide fuse structure with 1.0 μm pitch. They were processed with various laser energy levels in order to decide the nominal energy at a spot size of 0.7 μm 1/e² in diameter. FIGS. 8a-8b show laser-blasted links processed from 0.005 μJ to 0.090 μJ with 0.005 μJ step. One link out of every 4 was blasted in order to see damage to adjacent links. From visual inspections, we noticed that links started to open at 0.015 μJ and damage to the adjacent links due to excessive laser energy occurred at 0.055 μJ and above. Therefore, the nominal energy is (0.015+0.050)/2=0.0325 μJ. We rounded off the value and 0.030 μJ was selected as a nominal energy for this laser setting. Two slightly higher energies (0.040 μJ and 0.050 μJ) were also tried in order to see the susceptibility of adjacent links.

Laser energy studies were performed on all different structures and at 3 process energies, within the energy process window at a 0.7 μm 1/e² spot, were selected for each structure based on the results. Each laser energy was used to blast two sets of 600 links (a parallel set of 300 links and a serial set of 300 links) in order to ensure cut quality and no damage to adjacent links, a critical parameter as mentioned earlier.

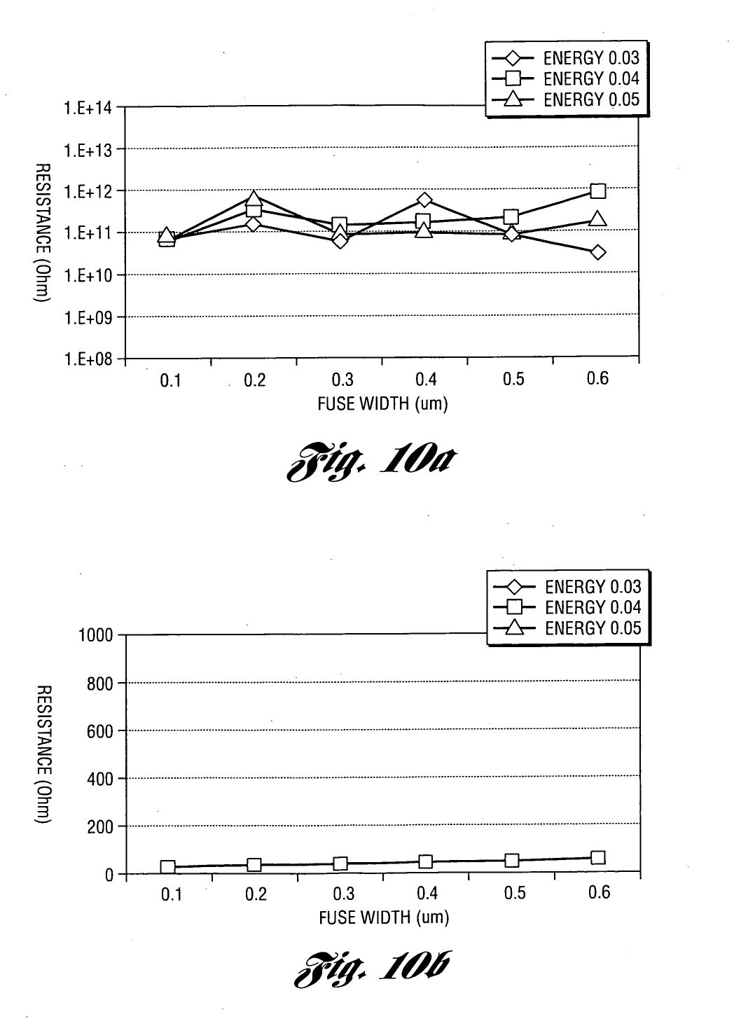

FIGS. 9a and 9b show SEM and FIB cross-sectional images of the 1.0 μm pitched 0.3 μm wide aluminum fuses that were processed with a laser energy of 0.04 μJ and 0.7 μm 1/e² spot in diameter. FIG. 9a displays a top-view image of the processed fuses. It shows that every other link was processed to check for the adjacent damage. The top view image reveals that fuses look wider than actual size because of the Si₃N₄ layer deposited after aluminum etching. The Si₃N₄ passivation layer can be seen in FIG. 9b as the bright layer on the top. The aluminum fuse can be observed right under the Si₃N₄ layer from the fuse in the middle. FIG. 9b shows that the fuse in the middle was not blown, whereas the two fuses on the sides were blown and aluminum was removed. The image also reveals aluminum debris around the cut sites, which was generated during the rupture of the aluminum links by the laser energy. The debris was one of the reasons for using slightly higher energy than nominal for actual processing of the metal link structures. This cross-sectional image of the processed links on the sides portrays a clean, reliable cut. All of the aluminum, as well as the TiN undercoating, was removed by the laser cutting process.

### Results and Discussion

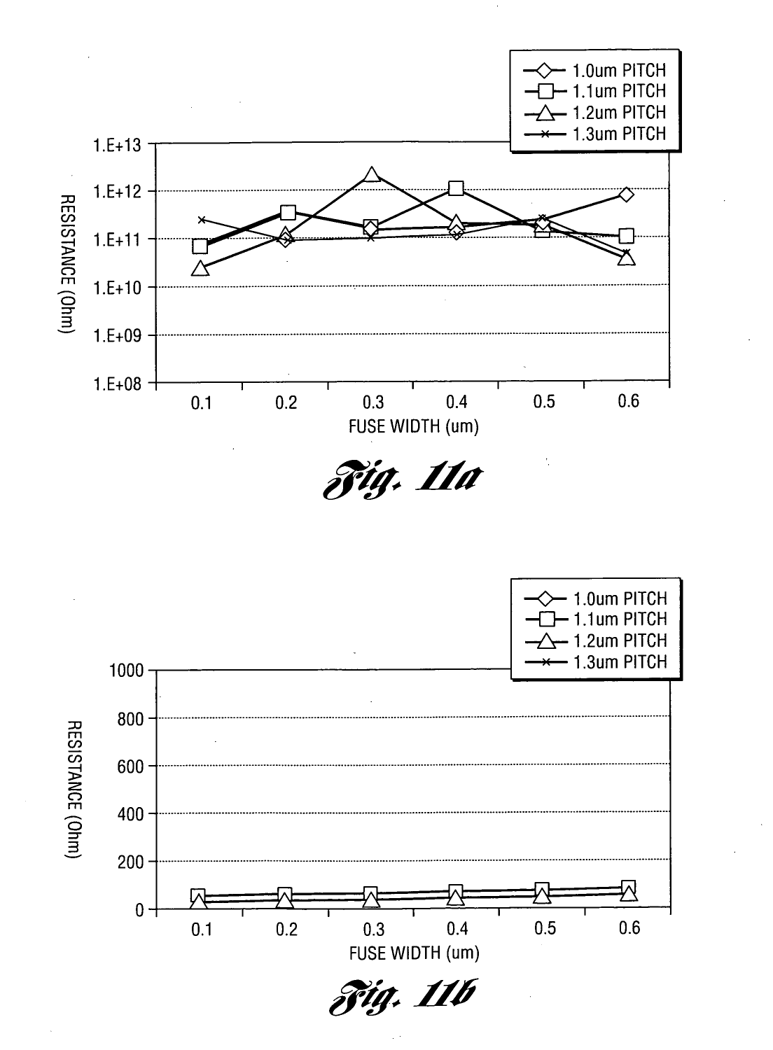

Various metal structure designs and laser parameters were tried and the results were measured electrically to ensure the possibility of implementing 532 nm wavelength on very fine pitch metal structures. FIGS. 10a and 10b show electrical measurement data particularly from 1.0 μm pitched metal fuse structures with various fuse widths. As previously mentioned, three (3) different energies were utilized and the two graphs in FIGS. 10a and 10b show the results from 3 energy levels (0.03, 0.04, and 0.05 μJ). FIG. 10a displays the resistance measurement data of 300 laser-processed paralleled links. The results display that all of the processed links were cut successfully throughout the various widths.

All the data show around 100 G Ω that is well beyond the value for acceptable laser link processing. The authors believe that there is still a range for optimum link width depending on particular fuse designs and laser parameters, and in-depth study is being performed and will be presented in a later publication.

The resistances of a series of fuses (the serial structures), which are next to processed fuses, were also measured. The results from electrical measurements of the unprocessed links are in FIG. 10b. The results reveal that none of the 3 sets (one set of 300 adjacent links next to 300 process links) were damaged and therefore kept their original resistance (below 60Ω per 300 links) after laser processing.

Average electrical resistance values for all the processed link structures including the data of 1.0 μm pitch structures (presented in FIG. 4) were obtained and are shown in FIGS. 11a and 11b. Each data point is an average value of 3 sets (900 links) processed with 3 different laser energy levels; 0.03 μJ, 0.04 μJ and 0.05 μJ were utilized for 1.0 μm and 1.1 μm pitched structures. Energies of 0.04 μJ, 0.05 μJ and 0.06 μJ were used for 1.2 μm and 1.3 μm pitched structures. Metal link structures pitched 1.4 μm and larger were also processed and showed successful results. The primary purpose of the experiment herein is to show advanced capability at or near 1.0 μm pitch, and the experimental data for 1.4 micron and coarser structures.

Results in FIGS. 11a and 11b show that all the metal structures pitched from 1.0 μm to 1.3 μm were successfully processed without any damage to adjacent link structures. There are small fluctuations of resistance curves around 100 G Ω and there are many other involved factors like laser processing system accuracy and imperfect fabrication process and so on. However, it is noted that this does not have statistical significance.

### Discussion

Microscopic observations and electrical measurements show that a 532 nm wavelength laser is fully capable of processing certain very fine pitch metal link structures down to 1.0 μm without any changes in current IC fabrication processes. The advantages of the 532 nm laser include larger DOF with smaller spot size compared with the current IR lasers.

At the very fine scale susceptibility to Silicon substrate damage, adjacent link damage, and damage to functional circuitry should all be considered simultaneously. In order to maximize the energy window, optical properties of the device materials is to be considered for additional experiments with different devices and various of combinations of device material.

Embodiments of the present invention may be used to process links arranged with not only very fine pitch layouts but also coarser pitch arrangements, for example, greater than 2 μm, 3 μm pitch, and the like. The above-noted LIA Handbook (reference 5, FIG. 15) shows “staggered links,” a well known configuration. As noted therein, the minimum pitch is twice the normal pitch. The computer-controlled motion system, which preferably provides for accuracy of 0.15 μm of better, may be programmed for increased speed when processing the coarser structures. For example, the speed may exceed 150 mm/sec. Typical links widths are well below 1 μm for the fine pitch arrangements, but may be increased somewhat for coarser pitch arrangements. When wafers having wider links are processed a suitable compromise between positioning accuracy and throughput may be chosen.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method of laser processing a multi-material device including a silicon substrate, conductive target and adjacent link structures, and at least one inner dielectric layer which separates the link structures from the silicon substrate, the method comprising:
generating at least one focused laser pulse having a predetermined visible or near UV wavelength long enough to sufficiently tolerate variations of at least one of the thickness and reflectance of a layer of the device or variations over a batch of the devices, the silicon substrate having a relatively high absorption coefficient at the predetermined wavelength and the at least one dielectric layer having a relatively low absorption coefficient at the predetermined wavelength; and
applying the at least one focused laser pulse having the predetermined wavelength into an approximate diffraction-limited spot during motion of the substrate relative to the at least one focused pulse, wherein the spot has a 1/e² spot diameter in a range of about 0.5-1.5 microns, the at least one focused laser pulse having an energy density over the spot sufficient to completely process the target link structure while avoiding undesirable change to the adjacent link structure, the substrate and any layers between the substrate and the link structures, and wherein the target link structure and the adjacent link structure have a pitch of about 2.0 microns or less.

2. The method as claimed in claim 1, wherein the step of generating generates a pulsed laser output having a wavelength below an absorption edge of the substrate and in the range of about 0.3-0.55 microns.

3. The method as claimed in claim 2, wherein the step of applying includes the step of directing the pulsed laser output at the target link structure at an incident beam energy sufficient to completely process the target link structure.

4. The method as claimed in claim 1, wherein the target link structure and the at least one laser pulse both have a position and further comprising generating computer-controlled timing signals synchronized with the position of the at least one pulse relative to the position of the target link structure.

5. The method as claimed in claim 4, wherein the step of generating computer-controlled timing signals is based on the position of the at least one laser pulse relative to the position of the target link structure.

6. The method as claimed in claim 5, further comprising providing an optical switch and switching the optical switch based on the timing signals to cause a plurality of focused laser pulses to be transmitted to the target link structure.

7. The method as claimed in claim 1, wherein the step of generating is performed with a pulsed laser subsystem having a near UV, blue or green wavelength.

8. The method as claimed in claim 7, wherein the subsystem includes a frequency doubled or tripled MOPA.

9. The method as claimed in claim 1, wherein the target link structure has a relatively high absorption at the predetermined wavelength.

10. The method as claimed in claim 1, wherein the pitch is about 1.5 microns or less.

11. The method as claimed in claim 1, wherein the diameter is about 0.7 microns.

12. The method as claimed in claim 11, wherein energy delivered to the target link structure when the pitch is about 1-1.3 microns is about 0.014 micro joules to less than about 0.055 micro joules over the 0.7 micron diameter.

13. The method as claimed in claim 1, wherein energy density over the diameter is in a range of about 1 J/cm² to about 20 J/cm².

14. A system of laser processing a multi-material device including a silicon substrate, conductive target and adjacent link structures, and at least one inner dielectric layer which separates the link structures from the silicon substrate, the system comprising:
means including a pulsed laser subsystem for generating at least one focused laser pulse having a predetermined visible or near UV wavelength long enough to sufficiently tolerate variations of at least one of the thickness and reflectance of a layer of the device or variations over a batch of the devices, the silicon substrate having a relatively high absorption coefficient at the predetermined wavelength and the at least one dielectric layer having a relatively low absorption coefficient at the predetermined wavelength; and
means for applying the at least one focused laser pulse having the predetermined wavelength into an approximate diffraction-limited spot during motion of the substrate relative to the at least one focused pulse, wherein the spot has a 1/e² spot diameter in a range of about 0.5-1.5 microns, the at least one focused laser pulse having an energy density over the spot sufficient to completely process the target link structure while avoiding undesirable change to the adjacent link structure, the substrate and any layers between the substrate and the link structures, and wherein the target link structure and the adjacent link structure have a pitch of about 2.0 microns or less.

15. The system as claimed in claim 14, wherein the means for generating generates a pulsed laser output having a wavelength below an absorption edge of the substrate and in the range of about 0.3-0.55 microns.

16. The system as claimed in claim 15, wherein the means for applying includes means for directing the pulsed laser output at the target link structure at an incident beam energy sufficient to completely process the target link structure.

17. The system as claimed in claim 14, wherein the target link structure and the at least one laser pulse both have a position and further comprising a computer programmed to generate timing signals synchronized with the position of the at least one pulse relative to the position of the target link structure.

18. The system as claimed in claim 17, wherein the computer is programmed to generate the timing signals based on the position of the at least one laser pulse relative to the position of the target link structure.

19. The system as claimed in claim 18, further comprising an optical switch and means for switching the optical switch based on the timing signals to cause a plurality of focused laser pulses to be transmitted to the target link structure.

20. The system as claimed in claim 14, wherein the pulsed laser subsystem has a near UV, blue or green wavelength.

21. The system as claimed in claim 20, wherein the subsystem includes a frequency doubled or tripled MOPA.

22. The system as claimed in claim 14, wherein the target link structure has a relatively high absorption at the predetermined wavelength.

23. The system as claimed in claim 14, wherein the pitch is about 1.5 microns or less.

24. The system as claimed in claim 14, wherein the diameter is about 0.7 microns.

25. The system as claimed in claim 24, wherein energy delivered to the target link structure when the pitch is about 1-1.3 microns is about 0.014 micro joules to less than about 0.055 micro joules over the 0.7 micron diameter.

26. The system as claimed in claim 14, wherein energy density over the diameter is in a range of about 1 J/cm² to about 20 J/cm².

27. The method of claim 1 wherein the multi-material device includes a multi-layer stack, the stack having at least one dielectric layer over one or more of the link structures.

28. The system of claim 14 wherein the multi-material device includes a multi-layer stack, the stack having at least one dielectric layer over one or more of the link structures.

29. The method of claim 4 wherein the diffraction-limited spot is centered about the target link structure to within about 0.15 μm, wherein damage to the adjacent link structure is avoided.

30. The system of claim 17 wherein the diffraction-limited spot is centered about the target link structure to within about 0.15 μm, wherein damage to the adjacent link structure is avoided.

31. The method of claim 1 wherein the step of generating produces laser pulses at a pulse repetition rate of about 70 KHz or greater.

32. The system of claim 14 wherein the means for generating produces laser pulses at a pulse repetition rate of about 70 KHz or greater.

33. The method of claim 4 wherein the multi-material device also includes conductive link structures having a pitch of about 2.0 microns or greater, and wherein the timing signals adjust speed of movement of the substrate based on the pitch of about 20 microns or greater so as to provide for an improvement in throughput.

34. The system of claim 17 wherein the multi-material device also includes conductive link structures having a pitch of about 2.0 microns or greater, and wherein the computer is programmed to generate timing signals which adjust speed of movement of the substrate based on the pitch of about 2.0 microns or greater so as to provide for an improvement in throughput.

35. The system of claim 14 wherein the pulsed laser subsystem includes a diode-pumped, frequency-doubled laser, the laser having an infrared (IR) fundamental wavelength and a minimum available pulse repetition rate of at least 50 KHz with available output energy of about 4 μJ or greater at the minimum available pulse repetition rate, residual IR of less than 1% of total power, peak-peak stability of about 5% or better, and output beam quality corresponding to M² of about 1.1 or better.
